(19) United States
(12) Patent Application Publication
(10) Pub. No.: US 2018/0328646 A1
(43) Pub. Date: Nov. 15, 2018

(54) Timer for a cooling appliance

(71) Applicant: Gregg Wood, Indianapolis, IN (US)

(72) Inventor: Gregg Wood, Indianapolis, IN (US)

(21) Appl. No.: 15/974,778

(22) Filed: May 9, 2018

Related U.S. Application Data
(60) Provisional application No. 62/504,234, filed on May 10, 2017.

(51) Int. Cl. F25D 21/00; H01H 43/04; H01H 43/02

(52) U.S. Cl. CPC F25D 21/008; F25D 21/006; G01R 19/2503; H01H 43/024; F25B 2600/23; H01H 43/04

(57) ABSTRACT

The system comprises an electronic timer circuit in a housing. The system having an automatic voltage sensor, a handheld tool, and a tool storage location. The sensor eliminates the need for manual voltage selection. The handheld tool connects to the circuit via a USB cable and is storable about the housing. The tool processes data it receives from the circuit and displays various information to a user.

### CROSS-REFERENCE TO RELATED APPLICATIONS

The present application claims the benefit of U.S. Provisional Patent Application No. 62/504,234, filed May 10, 2017, the entirety of which is hereby incorporated by reference, including its specification.

### BACKGROUND

Appliances, such as refrigerators, chillers, heaters, HVAC equipment, lighting, and the like, are used every day in commercial and residential environments. Appliances have functions, such as a defrost function, that must be controlled according to very specific cycles of time. Appliance technicians will utilize electronic timers to control these functions.

These timers are not an integrated part of the appliance and introduce many maintenance problems. The nature of the locations where these are installed often involve different voltages. Technicians use different timer models for different voltages or will use a manual configurable DIP switch to make adjustments in the field for the different power supply voltage levels. Additionally, there are large expanses of time between maintenance visits for the timers or the appliance being controlled. There is no convenient way for a field technician to assess the past performance of the timer that occurred during its being placed into operation. Currently, to determine the problem with a defrost timer, a field technician needs to start from scratch and tests each component for failure.

There is a need in the industry for an apparatus that is easy to use, inexpensive, and assists with assessing the performance of timers via a handheld tool. A need for a timer that provides automatic voltage selection, and also allows for storage of the handheld tool.

### SUMMARY

The present invention is directed to an apparatus that satisfies this need. The apparatus comprises a timer circuit with a timer that can be connected to a cooling appliance, a refrigerator for example, that controls the operation of an appliance's function, its defrost function for example. A tool is attachable and detachable to the timer. The inventor envisions the tool attaching and detaching via a cable attached to a port on the timer circuit. The tool processes electronic information from the timer circuit and presents important troubleshooting information about the cooling appliance's operations. The tool presents information to a user that results from the processing of data received from the timer's electronic circuitry.

The timer circuit also has a sensor electronically attached which automatically senses and adjusts for different power supply voltage levels required to be supplied to the timer. This eliminates the need for manual adjustments in the field which would result from different voltage level power sources.

The system is used to control functions of a cooling appliance, to make it easy to install a replacement timer regardless of voltage levels, and to provide informative information from the system to be displayed via a handheld tool which is read by a field technician.

Timer circuitry is programmed and capable of storing electronic data related to the operation of a cooling appliance's defrost cycles. The handheld reader is able to interpret the data and display the electronic data on a digital display that is part of the reader. Such data might include information relating to the on and off cycling of the appliances defrost cycle.

In a preferred embodiment of the invention, the handheld reader can download nine different historical defrost cycle records of a timer. Each of the timer's historical records includes data on thirty defrost cycles. The data includes a defrost time, a refrigeration time, termination times, any abnormal cycling times, and any abnormal defrost terminations.

An important function of the reader is its ability to provide information on defrost cycles that would indicate whether the cooling appliance might be damaging to food stored within the appliance. Specifically, an abnormal defrost terminate readout shown on the handheld reader, showing as “P/T” for instance, means the defrost time is set too long and the cooling appliance's will get too hot during defrost cycle. The appliance's defrost will be terminated by the machine's pressure/temperature sensor before an optimum defrost time is reached. This will essentially damage the food. The hand held unit can provide this information to serviceman, and give them enough information to adjust the defrost interval on the timer and protect food.

The timer circuitry in a preferred embodiment stores this data on an integrated circuit labeled IC1 to store the historical defrost cycle information. This data is retrieved by the handheld reader. The data is not lost even if the timer loses power.

A service technician performing maintenance on an appliance that includes the inventive timer can follow a simple method for troubleshooting and repairing or making adjustments to the timer function. First, after encountering the appliance the service technician will locate the inventive timer. Opening the timer he or she will review indicator lights that tell whether there is a defrost error. If desired, the service technician can then locate a handheld reader which is best if stored within the timer housing or case. The service technician then connects the handheld reader to a timer circuitry using a USB cable that connects to a USB port located on the timer circuitry. On the handheld reader there is located a “timer” button which the technician presses. Pressing up or down buttons on the handheld unit causes numbered data records to scroll on the handheld reader's display. The technician can select, there is a select button on the reader, the numbered record depending on which timer cycle record he or she would like to read about further. After selecting a record, the technician will press and hold a “download” button located on the handheld unit until the unit and the timer communicate and data is transferred, hold time is approximately three seconds. Timer electronic circuitry will download defrost cycle data specific to the chosen record and display the cycle data on the handheld reader. The last thirty defrost cycle data entries for the record are transferred.

The handheld unit will store the defrost cycle data downloaded until a user downloads a different record from the timer, then the data stored on the handheld unit will be overwritten. A service person can also can press a “delete” button for about three seconds to delete the selected record from the handheld unit.

The preferred embodiment of the inventive timer is a versatile replacement for other appliance timers. It can be used to replace at least twelve different models of other mechanical timers. It uses the same connection configuration regardless of whether it is being used on 110 volt or 220 volt power supply. Paper labels are provided with the timer to assist an installer in determining the proper configuration of wiring to use depending on the timer that is being replaced.

In another embodiment of my invention, a timer for a cooling appliance has a timer circuit that is attachable and detachable to an appliance. The timer circuit having a connection port, a cable, and a tool. The tool works best with a handheld electronic device with a display for presenting data to a technician and buttons for interacting with the device. This handheld reader is attachable and detachable to the timer circuit via the connection port and the cable. The handheld reader processes electronic information that is digitally stored on the timer circuit. The data is stored on an integrated circuit. The tool presents data that is derived from this processed electronic information to a technician working on the cooling appliance.

The timer includes a sensor that has a plurality of controls and is attached to the timer circuit. The sensor can automatically determine a value of a voltage that is supplied to the timer circuit from an external power source and adjust the timer circuit to accommodate the voltage. This allows a technician that is making a service call to fix an appliance to bring just one timer with them. If a timer on the appliance needs to be replaced, this embodiment of the inventive timer will work as a replacement regardless of the voltage requirement of the timer that is being replaced. I provide labels that go over the terminal block of the timer to assist the technician when they are connecting up wires and jumpers to replace a timer. The labels identify the wires to use on the new inventive timer depending on the model of timer being replaced. So a technician would apply a terminal block label to this embodiment of the inventive timer's terminal block and select the appropriate entry in a cross reference table provided. The technician would then use the identified Terminal Block label, apply to the circuit board and wire per the original wiring or the wiring diagrams indicated. Always being sure to identify the placement and use of the Factory Installed Jumper, if required.

I find that it is best if the timer circuit, the handheld reader, the cable and the sensor are all enclosed in a case and attached to an appliance. The case can be locked or made weather tight to withstand the outside elements.

These and other features, aspects and advantages of the present invention will become better understood with regard to the following description, appended claims, and accompanying drawing where:

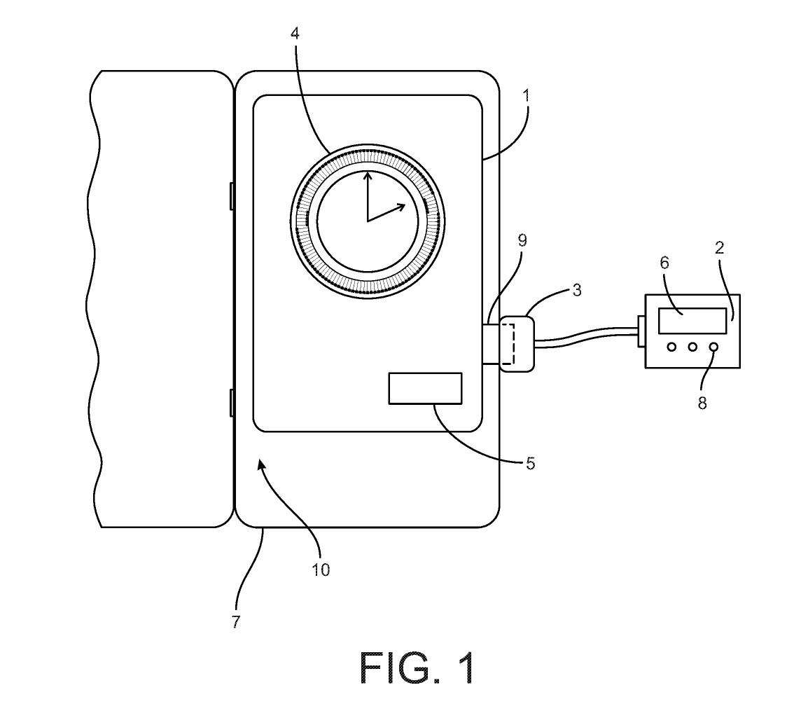

FIG. 1 shows an apparatus used to control appliances.

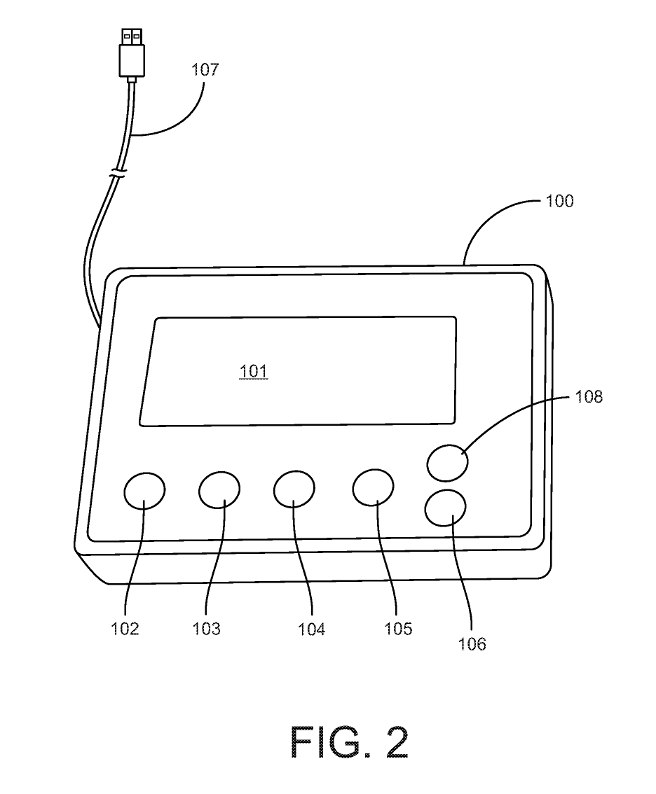

FIG. 2, shows a perspective view of an embodiment of a handheld unit of the present invention.

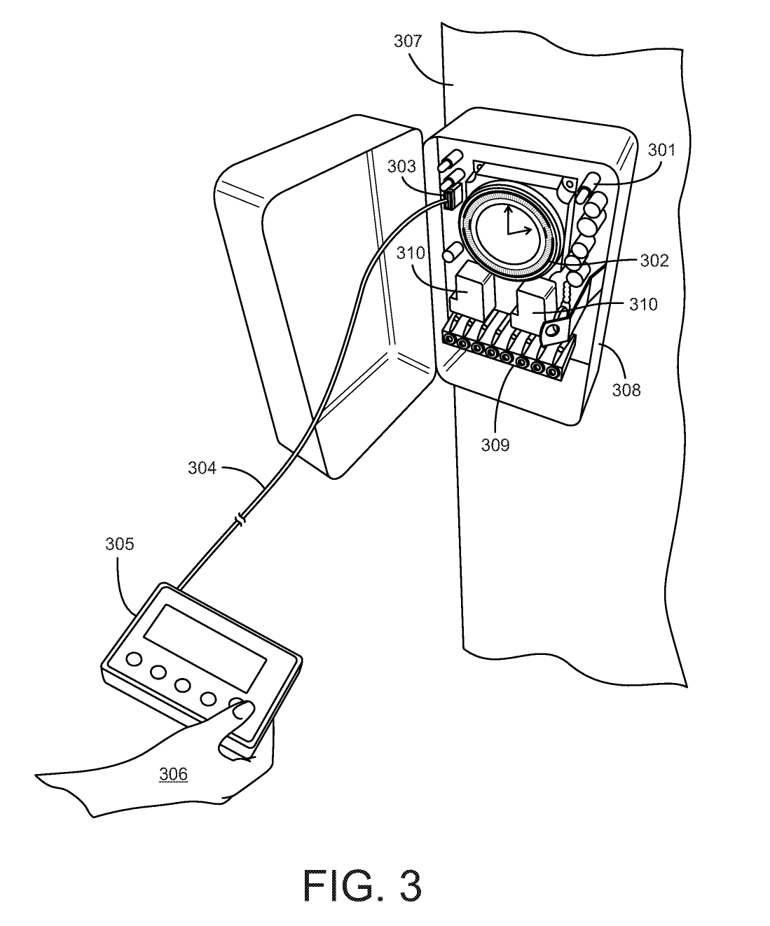

FIG. 3, shows a perspective view of an embodiment of the inventive timer being used during troubleshooting by a technician.

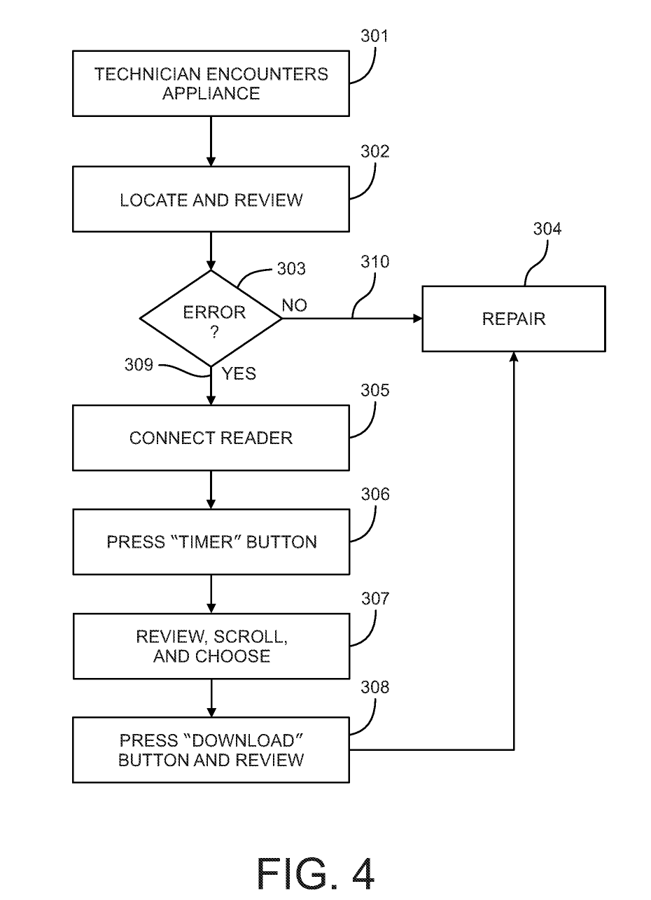

FIG. 4, shows a block diagram for a method embodiment for troubleshooting an embodiment of the timer.

### DESCRIPTION

### Overview.

As shown in FIG. 1, an apparatus according to the present invention that is used to control appliances, such as a refrigerator to name one example, comprises a housing 7, an electronic timer circuit 1 with a timer 4, a handheld tool 2 that is attachable and detachable to the timer circuit 1 at port 9 via a USB cable 3. The handheld tool 2 has a plurality of controls 8 attached. The housing 7 accommodates the storage of the handheld tool 2 such as via a space within the housing 10. The handheld tool 2 having an electronic display 6 where data is presented to a user. The timer circuit 1 have an automatic voltage sensor 5 that eliminates the need for manual selection of different power source levels.

As shown in FIG. 2, a perspective view of an embodiment of a handheld unit of the present invention comprises, a handheld reader 100. The handheld reader 100 being connected via a USB cable 107 to an inventive timer similar to that shown in FIG. 1. There are a plurality of buttons on the handheld reader that have different functions when pressed. There is a select button 102, a download button 103, a delete button 104, a P/T terminate button 105, a down button 106, and an up button 108. A user is presented various electronic data that appears on the display 101 at various times.

As shown in FIG. 3, a perspective view of an embodiment of the inventive timer being used during troubleshooting by a technician comprises a technician 306 that has approached a cooling appliance 307. The cooling appliance 307 having attached to it a timer system 308. The timer system having electronic circuitry 302. One component of the electronic circuitry is an LED light 301 that, when lit, indicates that the cooling appliance 307 has experienced a defrost cycle error, such as the defrost cycle running for too long a time period. This would be dangerous for the items inside the appliance.

The technician 306 can use a handheld reader 305 that connects to the timer 308 via a USB cable 304. The handheld reader 305 will provide to the technician 306 a means for reviewing electronic data that is informative with respect to defrost cycles that prompted the LED light 301 to indicate an error has occurred. The connection block 309 is labeled to indicate to the technician the proper wiring configuration needed.

As shown in FIG. 4, a method for troubleshooting an embodiment of the timer comprises, a first step 301 where a technician encounters an inventive timer. This usually occurs because an owner of a cooling appliance has requested service and the technician is dispatched to the location where the cooling appliance with a timer is located. The technician next will locate the timer and review 302 its LED indicators for error messages 303. If no error 310 is found or if the technician determines that no troubleshooting is necessary, then repairs or adjustments are made and the job is complete 304.

If an error is indicated 309, or the technician decides that troubleshooting is needed then a handheld reader is removed from its storage location within the timer's housing. Next, the technician uses a provided USB cable and connects the handheld reader unit to the timer 305. The USB cable will plug into a USB port that is a component of the timer circuitry. Next the “timer” button is pressed 306. This causes the timer to communicate with the handheld unit. Electronic data that was stored on the timer's circuitry is now available for viewing on display of the handheld unit. The technician will next scroll through data that is presented on the display of the handheld reader 307. Once a record of interest, the record containing defrost cycle data related to the operation of the cooling apparatus, is chosen then the technician will hit the download button and review the defrost cycle data 308. Analyzing the defrost cycle data allows the technician to determine the proper repairs or adjustments needed 304.

Although the present process has been described in considerable detail with the reference to certain preferred versions thereof, other versions are possible. For example, the connection between the reader and the timer could be wireless. Or the timer could communicate more detailed cycle data to the reader. Therefore, the spirit and scope of the appended claims should not be limited to the description of the preferred versions contained herein.

Any element in a claim that does not explicitly state “means for” performing a specified function, or “step for” performing a specific function, is not to be interpreted as a “means” or “step” clause as specified in 35 U.S.C. § 112, ¶ 6.

What I claim is:

1. A timer for a cooling appliance, the timer comprising:
a timer circuit;
the timer circuit being attachable and detachable to an appliance via a terminal block;
the timer circuit having a connection port;
a cable;
a tool;
the tool being attachable and detachable to the timer circuit via the connection port and the cable;
the tool capable of processing electronic information that is digitally stored on the timer circuit;
the tool presents data derived from the processed electronic information to a user;
a sensor;
the sensor having a plurality of controls;
the sensor being attached to the timer circuit;
the sensor being configured to automatically determine a value of a voltage that is supplied to the timer circuit from an external power source and adjust the timer circuit to accommodate the voltage.

2. The apparatus of claim 1 wherein a user can connect to, interpret, and read embedded data related to the historical performance of the appliance that is received from the timer circuit.

3. The apparatus of claim 1 wherein the sensor automatically sensing and adjusting eliminates the need for a user of the apparatus to manually alter electrical wiring in order to accommodate different power supply voltage levels being supplied to the timer circuit.

4. The apparatus of claim 1 wherein the tool is wirelessly connectable and disconnectable to the timer circuit.

5. The apparatus of claim 1 wherein the tool is handheld and presents data to a user that is relevant to the timer's operations.

6. The apparatus of claim 1 further comprising the timer being located within a timer case;
the tool capable of being conveniently stored in the timer case, the timer case being secured to the appliance.

7. The apparatus of claim 1 wherein the terminal block is capable of receiving alphanumeric markings.

8. A method of using a portable timer for a cooling appliance and a handheld reader unit to troubleshoot defrost cycle operations, the timer including a timer circuit that is attachable and detachable to the cooling appliance, the timer further including a connection port and a cable, a handheld reader unit being attachable and detachable to the timer circuit via the connection port and the cable, the handheld reader unit processing electronic information from the timer circuit and presenting data to a user, a sensor having a plurality of controls and the sensor being attached to the timer circuit and capable of automatically sensing and adjusting for different voltage levels supplied to the timer circuit, the method comprising:
a first step of a user encountering an inventive timer;
next locating the timer and review it for indications of error messages;
then if the user determines that no troubleshooting is necessary, then making repairs or adjustments to the cooling appliance, however if an error is indicated then a handheld reader is removed by the user from a storage location within the timer's housing;
next, the technician uses a cable and connects the handheld reader to the timer;
next the “timer” button is pressed which causes the timer to communicate with the handheld unit, electronic data that was stored on the timer's circuitry is now available for viewing on display of the handheld unit;
then the technician will scroll through data that is presented on the display of the handheld reader and choose a record of interest and analyze the defrost cycle data related to the operation of the cooling appliance;
next the technician determines the proper repairs or adjustments needed and completes the job.

9. A method of using a portable timer for a cooling appliance and a handheld reader unit to troubleshoot defrost cycle operations, the timer including a timer circuit that is attachable and detachable to the cooling appliance, the timer further including a connection port and a cable, a handheld reader unit being attachable and detachable to the timer circuit via the connection port and the cable, the handheld reader unit processing electronic information from the timer circuit and presenting data to a user, a sensor having a plurality of controls and the sensor being attached to the timer circuit and capable of automatically sensing and adjusting for different voltage levels supplied to the timer circuit, the method comprising:
encountering the cooling appliance including an inventive timer;
locating the timer and reviewing for error indications;
in response to an absence of error indications indicating no need for troubleshooting, making repairs and/or adjustments to the cooling appliance;
in response to an error indication being present, troubleshooting the cooling appliance by:
removing a handheld reader from a storage location within the timer housing;
connecting the handheld reader to the timer with a cable;
initiating communication between the timer and the handheld unit to enable historical records from the timer to be read from the handheld unit;
identify a relevant historical record; and
determine appropriate repairs and/or adjustments in accordance with the relevant historical record.
